(19) United States
(12) Patent Application Publication
(10) Pub. No.: US 2013/0169123 A1
(43) Pub. Date: Jul. 4, 2013

(54) ENCLOSURE ASSEMBLY

(71) Applicant: XIU-QUAN HU, Shenzhen City (CN)

(72) Inventor: XIU-QUAN HU, Shenzhen City (CN)

(21) Appl. No.: 13/656,452

(22) Filed: Oct. 19, 2012

(30) Foreign Application Priority Data
Dec. 29, 2011 (CN) 201110450644.7

(51) Int. Cl. H05K 7/14; H05K 5/02

(52) U.S. Cl. 312/223.1

(57) ABSTRACT

An enclosure assembly includes an enclosure, a protecting member, and a printed circuit board. The protecting member includes a mounting portion, a connecting portion connected to the mounting portion, and a protecting portion connected to the connecting portion. The mounting portion is secured in the enclosure to enable the protecting portion to be exposed out of the enclosure. The printed circuit board includes a printed circuit board body and an inserting end extending from the printed circuit board along a extending direction. The printed circuit board body is secured in the enclosure. The inserting end is exposed out of the enclosure and is located on the protecting portion. A length of the inserting end is smaller than a length of the protecting portion along the direction.

### BACKGROUND

1. Technical Field

The disclosure generally relates to enclosure assemblies, especially, to an enclosure assembly with a protecting member for protecting a printer circuit board (PCB).

2. Description of Related Art

A conventional server includes an enclosure and a PCB mounted in the enclosure. The PCB includes an inserting end exposed out of the enclosure. The server is mounted to a rack frame to enable the inserting end to connect to another PCB. During the process, the inserting end may be damaged due to impact with the rack frame.

Thus, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an enclosure assembly.

FIG. 2 is an exploded, isometric view of a server of FIG. 1.

FIG. 3 is an isometric view of a protecting member.

FIG. 4 is an assembled view of the server of FIG. 2.

FIG. 5 is a pre-assembled view of the enclosure assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

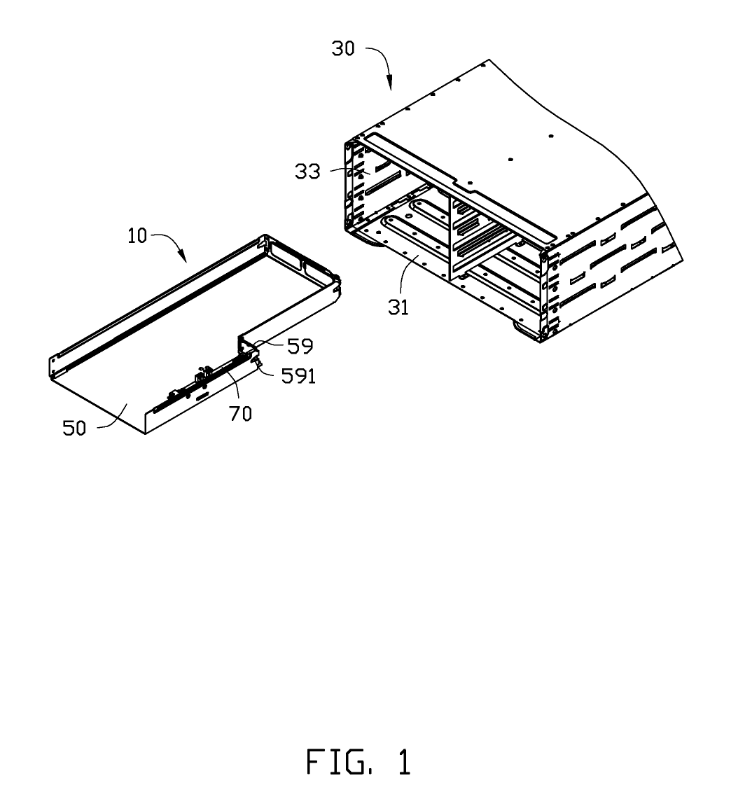

Referring to FIG. 1, one embodiment of an enclosure assembly is shown. The enclosure assembly includes a server 10 and a rack frame 30, for receiving the server 10. The server 10 includes an enclosure 50, a PCB 70 mounted in the enclosure 50, and a protecting member 90 for protecting the PCB 70.

The rack frame 30 includes a bottom wall 31 and three sidewalls 33 perpendicularly extending from the bottom wall 31. The three sidewalls 33 are substantially parallel to each other.

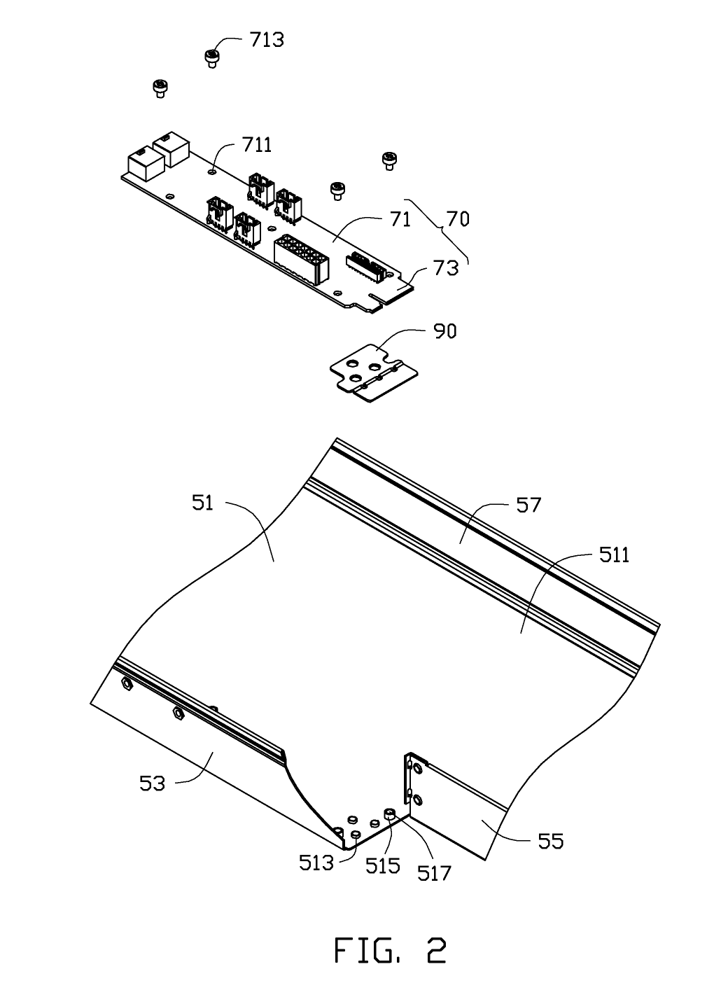

Referring to FIG. 2, the enclosure 50 includes a bottom panel 51, a first side panel 53 extending from the bottom panel 51, a second side panel 55 extending from the bottom panel 51, and a third side panel 57 extending from the bottom panel 51. The first side panel 53, the second side panel 55, and the third side panel 57 are substantially perpendicular to the bottom panel 51. The first side panel 53, the second side panel 55, and the third side panel 57 are substantially parallel to each other. A distance between the third side panel 57 and the first side panel 53 is greater than a distance between the third side panel 57 and the second side panel 55. A length of the third side panel 57 is substantially equal to a total length of the first side panel 53 and the second side panel 55. The enclosure 50 includes a connecting panel 59 connected between the second side panel 55 and the first side panel 53. The connecting panel 59 is substantially perpendicular to the bottom panel 51 and the second side panel 55. The connecting panel 59 defines a mounting opening 591. The first side panel 53 and the second side panel 55 extend from the connecting panel 59 along opposite directions. The bottom panel 51 includes a bottom panel body 511, a plurality of securing portions 513 extending from the bottom panel body 511, and a plurality of mounting protrusions 515 extending from the bottom panel body 511. Each mounting protrusion 515 defines a mounting hole 517.

The PCB 70 includes a PCB body 71 and an inserting end 73 extending from the PCB body 71 along a direction substantially perpendicular to the connecting panel 59. The inserting end 73 is connected to an inserting slot of another PCB (not shown). The PCB body 71 defines a plurality of through holes 711 corresponding to the mounting holes 517.

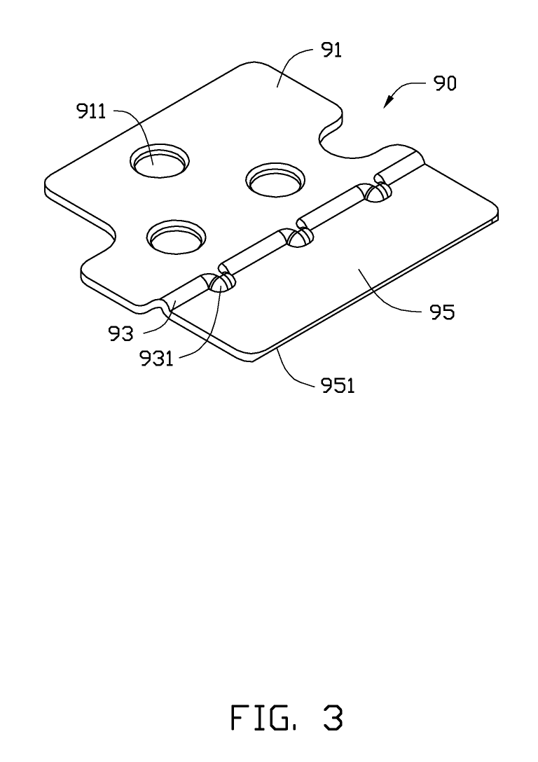

Referring to FIG. 3, the protecting member 90 includes a mounting portion 91 substantially parallel to the bottom panel body 511, a connecting portion 93 connected to the mounting portion 91, and a protecting portion 95 extending from the connecting portion 93. The mounting portion 91 defines a plurality of securing holes 911 corresponding to the securing portions 513. The mounting portion 91 is substantially parallel to the protecting portion 95. The connecting portion 93 includes a plurality of connecting protrusions 931. The protecting portion 95 defines an inclining surface 951.

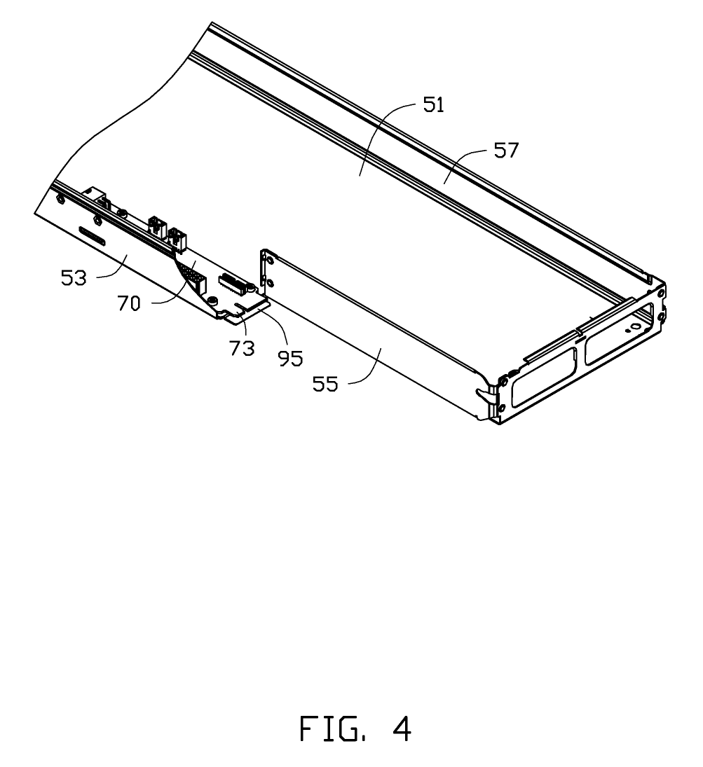

Referring to FIG. 4, in assembly of the server 10, the securing holes 911 of the protecting member 90 are secured to the securing portions 513 via rivet joint. At this time, the protecting portion 95 and the bottom panel body 511 are in the same plane. The through holes 711 of the PCB 70 are aligned with the mounting holes 517 of the bottom panel 51. A plurality of fasteners 713 extends through the through holes 711 to be screwed in the mounting holes 517, thereby securing the PCB 70 the bottom panel body 511. The inserting end 73 of the PCB 70 is located on the protecting portion 95 of the protecting member 90. The length of the inserting end 73 is smaller than the length of the protecting portion 95 along the direction substantially perpendicular to the connecting panel 59. A gap is defined between the inserting end 73 and the protecting portion 95.

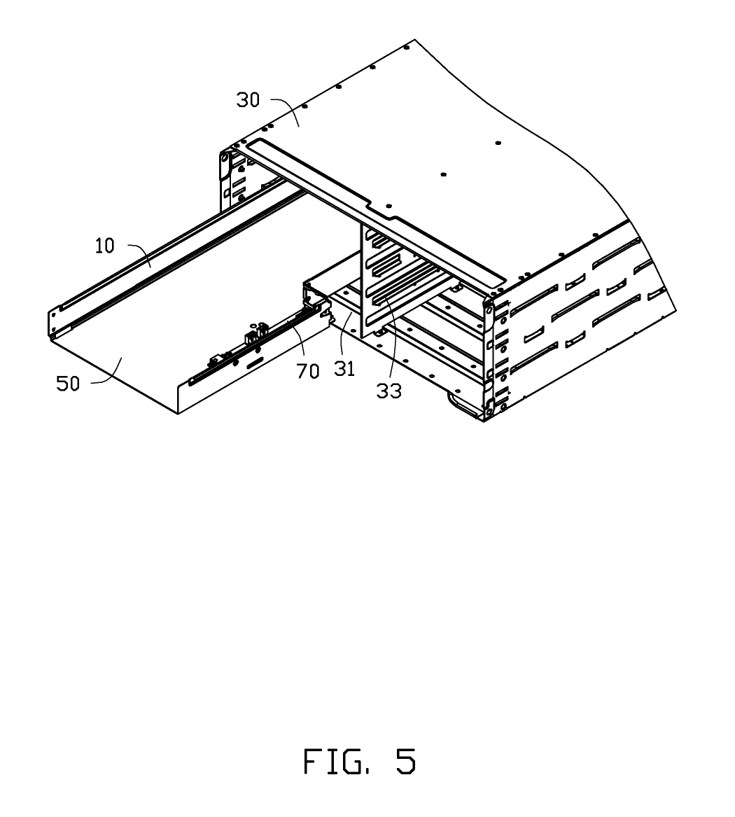

Referring to FIG. 5, in assembly of the server 10 to the rack frame 30, the server 10 is placed between the two sidewalls 33. The server 10 is pushed into the rack frame 30 to enable the inserting end 73 to be inserted in an inserting slot of another PCB mounted in the rack frame 30.

It is to be understood, however, that even though numerous characteristics and advantages have been set forth in the foregoing description of embodiments, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An enclosure assembly, comprising:
an enclosure;
a protecting member, the protecting member comprises a mounting portion, a connecting portion connected to the mounting portion, and a protecting portion connected to the connecting portion; and the mounting portion is secured in the enclosure to enable the protecting portion to be exposed out of the enclosure; and
a printed circuit board, the printed circuit board comprising a printed circuit board body and an inserting end, extending from the printed circuit board along an extending direction; the printed circuit board body is secured in the enclosure; the inserting end is exposed out of the enclosure and is located on the protecting portion; and a length of the inserting end is smaller than a length of the protecting portion, along the extending direction.

2. The enclosure assembly of claim 1, wherein the enclosure comprises a bottom panel, a first side panel, a second side panel, and a connecting panel connected between the second side panel and the first side panel; the first side panel and the second side panel extend from the bottom panel and are substantially perpendicular to the bottom panel; the connecting panel defines a mounting opening; and the mounting portion is secured to the bottom panel and the protecting portion extends through the mounting opening to be exposed out of the enclosure.

3. The enclosure assembly of claim 2, wherein the first side panel and the second side panel are substantially parallel to each other and extend from the connecting panel along opposite directions.

4. The enclosure assembly of claim 3, wherein the enclosure further comprises a third side panel extending from the bottom panel, and the third side panel is substantially parallel to the first side panel.

5. The enclosure assembly of claim 4, wherein a length of the third side panel is substantially equal a total length of the first side panel and the second side panel, along the extending direction.

6. The enclosure assembly of claim 2, wherein the extending direction is substantially perpendicular to the connecting panel.

7. The enclosure assembly of claim 2, wherein the bottom panel comprises a bottom panel body and a plurality of mounting protrusions, extending from the bottom panel body; each of the plurality of mounting protrusions define a mounting hole; and the printed circuit board body defines a plurality of through holes corresponding to the mounting holes.

8. The enclosure assembly of claim 2, wherein the bottom panel comprises a bottom panel body and a securing portion extending from the bottom panel body; and the mounting portion defines a securing hole receiving the securing portion.

9. The enclosure assembly of claim 1, wherein the protecting portion comprises an inclining surface.

10. An enclosure assembly, comprising:
an enclosure, the enclosure comprising a bottom panel and a connecting panel, substantially perpendicular to the bottom panel, and the connecting panel defines a mounting opening;
a protecting member, the protecting member comprises a mounting portion, a connecting portion, connected to the mounting portion, and a protecting portion, connected to the connecting portion; and the mounting portion is secured to the bottom panel and the protecting portion extends through the mounting opening to be exposed out of the enclosure; and
a printed circuit board, the printed circuit board comprising a printed circuit board body and an inserting end, extending from the printed circuit board; the printed circuit board body is secured on the bottom panel and covers the mounting portion; the inserting end extends through the mounting opening to be exposed out of the enclosure and is located on the protecting portion; and a length of the inserting end is smaller than a length of the protecting portion, along an extending direction substantially perpendicular to the connecting panel.

11. The enclosure assembly of claim 10, wherein the enclosure further comprises a first side panel and a second side panel, extending from the bottom panel; the first side panel and the second side panel are substantially perpendicular to the bottom panel; and the connecting panel is connected between the first side panel and the second side panel.

12. The enclosure assembly of claim 11, wherein the first side panel and the second side panel are substantially parallel to each other and extend from the connecting panel along opposite directions.

13. The enclosure assembly of claim 12, wherein the enclosure further comprises a third side panel extending from the bottom panel and the third side panel is substantially parallel to the first side panel.

14. The enclosure assembly of claim 13, wherein a length of the third side panel is substantially equal a total length of the first side panel and the second side panel, along the extending direction.

15. The enclosure assembly of claim 10, wherein the bottom panel comprises a bottom panel body and a plurality of mounting protrusions, extending from the bottom panel body; each of the plurality of mounting protrusions define a mounting hole; and the printed circuit board body defines a plurality of through holes corresponding to the mounting holes.

16. The enclosure assembly of claim 10, wherein the bottom panel comprises a bottom panel body and a securing portion extending from the bottom panel body; and the mounting portion defines a securing hole receiving the securing portion.

17. The enclosure assembly of claim 10, wherein the protecting portion comprises an inclining surface.
